(19) United States
(12) Patent Application Publication
(10) Pub. No.: US 2025/0210500 A1
(43) Pub. Date: Jun. 26, 2025

(54) PACKAGE SUBSTRATE AND SEMICONDUCTOR PACKAGE

(71) Applicant: SAMSUNG ELECTRONICS CO., LTD., SUWON-SI (KR)

(72) Inventor: Youngchae JEON, Suwon-si (KR)

(21) Appl. No.: 18/894,361

(22) Filed: Sep. 24, 2024

(30) Foreign Application Priority Data
Dec. 21, 2023 (KR) 10-2023-0188276
Apr. 2, 2024 (KR) 10-2024-0044852

(51) Int. Cl. H01L 23/498; H01L 23/00

(52) U.S. Cl. CPC H01L 23/49838; H01L 23/49816; H01L 24/16; H01L 24/48; H01L 2224/16227; H01L 2224/48227

(57) ABSTRACT

A package substrate includes a base substrate. Upper pads are disposed on an upper surface of the base substrate. Lower pads are disposed on a lower surface of the base substrate. A plurality of interconnection patterns respectively connect the upper pads and the lower pads to each other. The plurality of interconnection patterns includes signal interconnection patterns and power interconnection patterns. At least one signal interconnection pattern includes a first pattern extending in a first direction and a plurality of second patterns protruding from the first pattern in a second direction perpendicular to the first direction. At least one power interconnection pattern surrounds the at least one signal interconnection pattern and has a shape corresponding to the first pattern and the plurality of second patterns. The at least one power interconnection pattern is a supply path for a ground voltage.

### CROSS-REFERENCE TO RELATED APPLICATION(S)

This application claims priority under 35 U.S.C. § 119 to Korean Patent Application No. 10-2023-0188276, filed on Dec. 21, 2023, in the Korean Intellectual Property Office (KIPO) and Korean Patent Application No. 10-2024-0044852, filed on Apr. 2, 2024 in KIPO, the disclosures of which are incorporated by reference in their entireties herein.

### 1. TECHNICAL FIELD

The present disclosure relates to a package substrate and a semiconductor package.

### 2. DISCUSSION OF RELATED ART

A semiconductor package may include a semiconductor chip and a package substrate on which the semiconductor chip is mounted. The package substrate may include interconnection patterns for transmitting signals to and from the semiconductor chip. The package substrate includes a base substrate with insulation and interconnection patterns formed on the base substrate. The interconnection patterns may electrically connect upper pads disposed on an upper surface of the package substrate with lower pads disposed on a lower surface of the package substrate, respectively. Since the length of the interconnection patterns varies depending on a position of each of the upper pads and the lower pads, the time required for a signal to be transmitted from the lower pads to the upper pads through the interconnection patterns may vary. Accordingly, various methods have been proposed to reduce differences in signal transmission delay despite differences in the physical length of the interconnection patterns formed on the package substrate.

### SUMMARY

An aspect of the present disclosure is to provide a package substrate and a semiconductor package including the same, which may reduce or eliminate a difference in transmission delay of signals transmitted through interconnection patterns, regardless of a difference in length of the interconnection patterns that transmit the signals.

According to an embodiment of the present disclosure, a package substrate includes a base substrate. A plurality of upper pads is disposed on an upper surface of the base substrate. A plurality of lower pads is disposed on a lower surface of the base substrate. A plurality of interconnection patterns respectively connects the plurality of upper pads and the plurality of lower pads to each other. The plurality of interconnection patterns includes signal interconnection patterns and power interconnection patterns. At least one signal interconnection pattern among the signal interconnection patterns includes a first pattern extending in a first direction and a plurality of second patterns protruding from the first pattern in a second direction perpendicular to the first direction. At least one power interconnection pattern among the power interconnection patterns surrounds the at least one signal interconnection pattern. The at least one power interconnection pattern has a shape corresponding to the first pattern and the plurality of second patterns. The at least one power interconnection pattern is a supply path for a ground voltage.

According to an embodiment of the present disclosure, a package substrate, includes a semiconductor chip mounted on the package substrate. The package substrate includes a base substrate. A plurality of upper pads is disposed on an upper surface of the substrate. A plurality of lower pads is disposed on a lower surface of the substrate. A plurality of interconnection patterns respectively connects the plurality of upper pads and the plurality of lower pads to each other. The plurality of interconnection patterns includes signal interconnection patterns and power interconnection patterns. At least one of the signal interconnection patterns includes a first pattern extending in a first direction and a plurality of second patterns protruding from the first pattern in a second direction perpendicular to the first direction. At least one power interconnection pattern among the power interconnection patterns surrounds the at least one signal interconnection pattern. The at least one power interconnection pattern has a shape corresponding to the first pattern and the plurality of second patterns. The at least one power interconnection pattern is a supply path for a ground voltage.

According to an embodiment of the present disclosure, a package substrate, includes a base substrate. A plurality of upper pads is disposed on an upper surface of the base substrate. A plurality of lower pads is disposed on a lower surface of the base substrate. A plurality of interconnection patterns respectively connects the plurality of upper pads and the plurality of lower pads to each other. The plurality of interconnection patterns includes signal interconnection patterns and power interconnection patterns. At least one signal interconnection pattern among the signal interconnection patterns includes a first pattern extending in a first direction and a plurality of second patterns protruding from the first pattern in a second direction perpendicular to the first direction. The package substrate includes a ground layer disposed on the lower surface of the base substrate. The ground layer has an area larger than an area of each of the plurality of interconnection patterns. The ground layer receives a ground voltage.

According to an embodiment of the present disclosure, among signal interconnection patterns, a signal interconnection pattern providing a relatively long signal transmission path and a signal interconnection pattern providing a relatively short signal transmission path may be formed to have different shapes from each other. The signal interconnection pattern providing a relatively short signal transmission path may be formed to have a first pattern and second patterns protruding from the first pattern, and at least one power interconnection pattern may be formed to surround the first pattern and the second patterns, thereby increasing the delay time of the signal interconnection pattern providing a relatively short signal transmission path. Accordingly, the difference in delay time between signal interconnection patterns can be reduced or eliminated.

Advantages and effects of the present application are not limited to the foregoing contents and may be more easily understood in the process of describing a specific embodiment of the present disclosure.

### BRIEF DESCRIPTION OF DRAWINGS

The above and other aspects, features, and advantages of embodiments of the present disclosure will be more clearly understood from the following detailed description, taken in conjunction with the accompanying drawings, in which:

FIG. 1 is a view schematically illustrating a package substrate according to an embodiment of the present disclosure;

FIGS. 2A and 2B are views schematically illustrating a semiconductor package according to embodiments of the present disclosure;

FIG. 3 is a view schematically illustrating a package substrate according to an embodiment of the present disclosure;

FIG. 4 is a perspective view schematically illustrating a portion of an interconnection pattern according to an embodiment of the present disclosure;

FIG. 5 is a cross-sectional view schematically illustrating an interconnection pattern taken along line A-A′ of FIG. 3 according to an embodiment of the present disclosure;

FIGS. 6A to 8C are views schematically illustrating a portion of an interconnection pattern according to embodiments of the present disclosure;

FIGS. 9A and 9B are enlarged views illustrating a portion of an interconnection pattern according to embodiments of the present disclosure;

FIG. 10 is a view schematically illustrating an interconnection pattern according to an embodiment of the present disclosure; and

FIG. 11 is a view schematically illustrating a semiconductor package according to an embodiment of the present disclosure.

### DETAILED DESCRIPTION OF EMBODIMENTS

Hereinafter, embodiments of the present disclosure will be described with reference to the accompanying drawings.

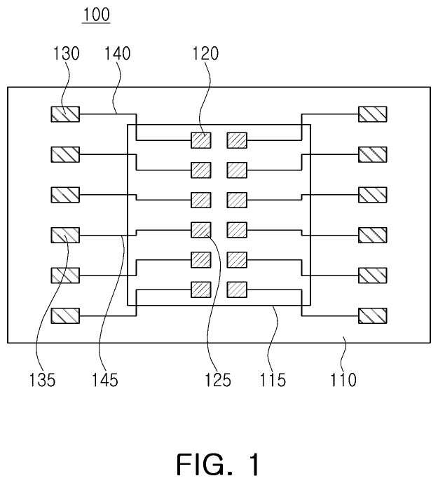

FIG. 1 is a view schematically illustrating a package substrate according to an embodiment of the present disclosure.

Referring to FIG. 1, a package substrate 100 according to an embodiment of the present disclosure may include a base substrate 110, upper pads 120 and 125, lower pads 130 and 135, and interconnection patterns 140 and 145. The upper pads 120 and 125 may be disposed on an upper surface of the base substrate 110, and the lower pads 130 and 135 may be disposed on a lower surface of the base substrate 110. For example, in an embodiment the upper pads 120 and 125 may be disposed in a mounting region 115 defined on the upper surface of the base substrate 110, and may be connected to (e.g., electrically connected thereto) a semiconductor chip mounted in the mounting region 115 through microbumps and the like.

In an embodiment, the interconnection patterns 140 and 145 may include signal interconnection patterns connecting (e.g., electrically connecting) each of the upper pads 120 and 125 and the lower pads 130 and 135 to each other and providing a transmission path for data signals and clock signals, and power interconnection patterns providing a transmission path for power voltage. However, since the positions of the upper pads 120 and 125 and the lower pads 130 and 135 are different from each other, at least a portion of the signal interconnection patterns 140 and 145 connecting the upper pads 120 and 125 and the lower pads 130 and 135 may have different lengths from each other. For example, when at least a portion of the signal interconnection patterns 140 and 145 have different lengths from each other, a difference may occur in the delay characteristics of signals transmitted to the signal interconnection patterns 140 and 145, and the characteristics of signals transmitted and received by the semiconductor chip mounted on the mounting region 115 may be deteriorated.

Referring to FIG. 1, a plurality of signal interconnection patterns 140 and 145 may be a first signal interconnection pattern 140 connecting (e.g., electrically connecting) a first upper pad 120 and a first lower pad 130 to each other, and a second signal interconnection pattern 145 connecting (e.g., electrically connecting) a second upper pad 125 and a second lower pad 135 to each other. As illustrated in FIG. 1, the shortest distance between the first upper pad 120 and the first lower pad 130 may be greater than the shortest distance between the second upper pad 125 and the second lower pad 135. Accordingly, when each of the first signal interconnection pattern 140 and the second signal interconnection pattern 145 is formed with the respective shortest distance, a length of the first signal interconnection pattern 140 may be greater than a length of the second signal interconnection pattern 145.

In an embodiment in which the length of the first signal interconnection pattern 140 may be greater than the length of the second signal interconnection pattern 145, the delay characteristics of a signal transmission path provided by the first signal interconnection pattern 140 may be different from the delay characteristics of a signal transmission path provided by the second signal interconnection pattern 145. As an example, assuming that the first signal interconnection pattern 140 provides a transmission path for a first data signal and the second signal interconnection pattern 145 provides a transmission path for a second data signal, the delay time of the first data signal may appear greater than the delay time of the second data signal. Accordingly, a difference may occur in the time at which the semiconductor chip receives each of the first data signal and the second data signal.

In an embodiment of the present disclosure, the second signal interconnection pattern 145 may form a first pattern extending in a first direction and a plurality of second patterns protruding from the first pattern in a second direction, perpendicular to the first direction. However, embodiments of the present disclosure are not necessarily limited thereto and the first and second directions may cross each other at various different angles. In an embodiment, a power interconnection pattern providing a ground voltage path and surrounding the second signal interconnection pattern 145 may be disposed around the second signal interconnection pattern 145.

By forming the second signal interconnection pattern 145 to include the first pattern and the second patterns, an area in which the second signal interconnection pattern 145 and the surrounding power interconnection pattern face each other may be expanded. The area in which the second signal interconnection pattern 145 and the surrounding power interconnection pattern face each other may be increased, thus increasing a magnitude of the capacitance generated between the second signal interconnection pattern 145 and the surrounding power interconnection pattern, and the delay time of the second data signal transmitted through the second signal interconnection pattern 145 may be increased. Accordingly, by forming the second signal interconnection pattern 145 to include the first pattern and the second patterns, the delay time of the second data signal may be increased. With an increase in the delay time of the second data signal, a difference between the delay time of the first data signal and the delay time of the second data signal may be reduced or eliminated, and in a semiconductor chip mounted on the package substrate 100, the first data signal and the second data signal may be easily aligned with the clock signal.

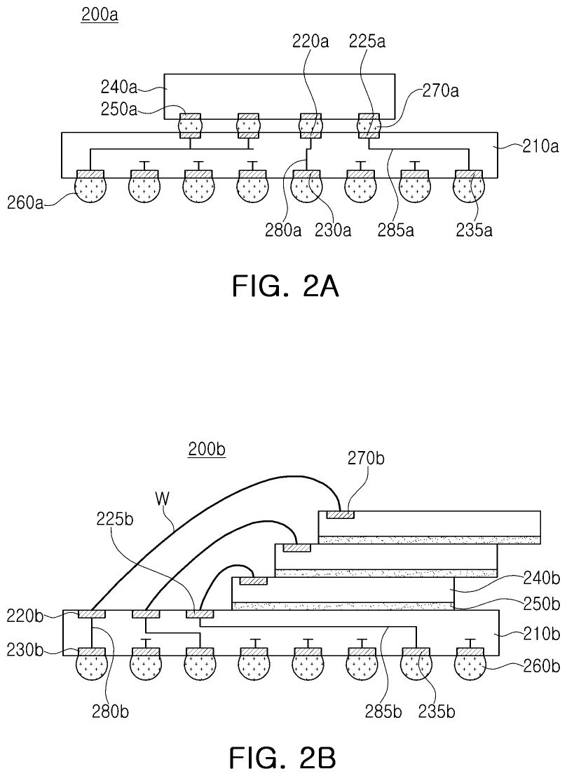

FIGS. 2A and 2B are cross-sectional views schematically illustrating a semiconductor package according to embodiments of the present disclosure.

Referring to FIG. 2A, a semiconductor package 200a according to an embodiment of the present disclosure may include a base substrate 210a, upper pads 220a and 225a, lower pads 230a and 235a, and a semiconductor chip 240a. The package substrate may include a base substrate 210a, upper pads 220a and 225a, and lower pads 230a and 235a, and the semiconductor chip 240a may include chip pads 250a formed on (e.g., disposed directly thereon) a surface opposing the package substrate. In an embodiment, each of the chip pads 250a of the semiconductor chip 240a and the upper pads 220a and 225a disposed on an upper surface of the package substrate may be connected to (e.g., directly connected thereto) microbumps 270a. In an embodiment, each of the lower pads 230a and 235a of the package substrate may be connected to (e.g., directly connected thereto) solder bumps 260a, and the solder bumps 260a may provide a connection to (e.g., electrical connection thereto) another external semiconductor device or substrate.

In an embodiment, a plurality of interconnection patterns 280a and 285a may be formed on the base substrate 210a, and the upper pads 220a and 225a may be connected to (e.g., electrically connected thereto) the lower pads 230a and 235a by the plurality of interconnection patterns 280a and 285a. In an embodiment, the upper pads 220a and 225a may be exposed on an upper surface of the base substrate 210a, and may be disposed to be relatively close to a center of the upper surface of the base substrate 210a in one direction, parallel to the upper surface of the base substrate 210a. Accordingly, in an embodiment the semiconductor chip 240a may have a center pad structure in which a plurality of chip pads 250a are disposed to be relatively close to the center. The upper pads 220a and 225a may be connected to (e.g., directly connected thereto) one surface of the microbumps 270a, such as a lower surface of the microbumps 270a.

According to an embodiment of the present disclosure, the plurality of signal interconnection patterns 280a and 285a may include a first signal interconnection pattern 280a electrically connecting the first upper pad 220a and the first lower pad 230a to each other and providing a transmission path for the first data signal, and a second signal interconnection pattern 285a electrically connecting the second upper pad 225a and the second lower pad 235a to each other and providing a transmission path for the second data signal. In an embodiment, the shortest distance between the second upper pad 225a and the second lower pad 235a may be greater than the shortest distance between the first upper pad 220a and the first lower pad 230a. Accordingly, when each of the first signal interconnection pattern 280a and the second signal interconnection pattern 285a is formed with the respective shortest distance, a length of the second signal interconnection pattern 285a may be greater than a length of the first signal interconnection pattern 280a.

In an embodiment in which the length of the second signal interconnection pattern 285a is greater than the length of the first signal interconnection pattern 280a, the delay time of the second data signal may be greater than the delay time of the first data signal. Accordingly, a difference may occur in the time at which the semiconductor chip 240a receives each of the first data signal and the second data signal.

According to an embodiment of the present disclosure, the first signal interconnection pattern 280a may form a first pattern extending in a first direction, parallel to the upper surface of the base substrate 210a, and a plurality of second patterns protruding from the first pattern in a second direction, perpendicular to the first direction, and parallel to the upper surface of the base substrate 210a. The first signal interconnection pattern 280a may be formed to include the first pattern and the second patterns, thus increasing a magnitude of the capacitance generated between the first signal interconnection pattern and at least one power interconnection pattern around (e.g., arranged to surround) the first signal interconnection pattern. The magnitude of the capacitance generated between the first signal interconnection pattern 280a and the surrounding power interconnection pattern may be increased, thus increasing the delay time of the first data signal. With the increase in the delay time of the first data signal, a difference between the delay time of the first data signal and the delay time of the second data signal may be reduced or eliminated to reduce or prevent deterioration of signal characteristics.

Referring to FIG. 2B, a semiconductor package 200b according to an embodiment of the present disclosure may include a plurality of semiconductor chips 240b, and a wire W. In an embodiment, the package substrate may include a base substrate 210b, upper pads 220b and 225b, and lower pads 230b and 235b, and the semiconductor chips 240b may include chip pads 270b formed on (e.g., disposed directly thereon) a surface opposite to a surface facing the package substrate. Each of the chip pads 270b of the semiconductor chips 240b and the upper pads 220b and 225b disposed on the upper surface of the package substrate may be connected with the wires W. Each of the lower pads 230b and 235b of the package substrate may be connected to (e.g., directly connected thereto) solder bumps 260b, and the solder bumps 260b may provide a connection to (e.g., electrical connection thereto) another external semiconductor device or substrate.

In an embodiment, a plurality of interconnection patterns 280b and 285b may be formed on the base substrate 210b, and the upper pads 220b and 225b may be connected to (e.g., electrically connected thereto) the lower pads 230b and 235b by the plurality of interconnection patterns 280b and 285b. In an embodiment, the upper pads 220b and 225b may be exposed on an upper surface of the base substrate 210b, and may be disposed to be relatively close to an edge of the upper surface of the base substrate 210b in one direction, parallel to the upper surface of the base substrate 210b. Accordingly, in an embodiment a semiconductor chip 240b may have an edge pad structure in which a plurality of chip pads 270b are disposed to be relatively close to the edge. The upper pads 220b and 225b may be connected to (e.g., directly connected thereto) an end of the wires W.

In an embodiment, a plurality of semiconductor chips 240b may be stacked on the upper surface of the package substrate. In an embodiment, the plurality of semiconductor chips 240b may be attached to each other by adhesive surfaces 250b disposed therebetween, and the plurality of semiconductor chips 240b may be stacked in a staircase structure in one direction. Accordingly, the chip pads 270b included in each of the semiconductor chips 240b may be exposed to the outside in a direction, perpendicular to the upper surface of the package substrate, and may be connected to (e.g., directly connected thereto) the other end of wires W.

According to an embodiment of the present disclosure, the plurality of signal interconnection patterns 280b and 285b may include a first signal interconnection pattern 280b connecting (e.g., electrically connecting) the first upper pad 220b and the first lower pad 230b to each other and providing a transmission path for a first data signal, and a second signal interconnection pattern 285b connecting (e.g., electrically connecting) the second upper pad 225b and the second lower pad 235b to each other and providing a transmission path for a second data signal. In an embodiment, the shortest distance between the second upper pad 225b and the second lower pad 235b may be greater than the shortest distance between the first upper pad 220b and the first lower pad 230b. Accordingly, when each of the first signal interconnection pattern 280b and the second signal interconnection pattern 285b is formed with the shortest distance, a length of the second signal interconnection pattern 285b may be greater than a length of the first signal interconnection pattern 280b.

In an embodiment in which the length of the second signal interconnection pattern 285b is greater than the length of the first signal interconnection pattern 280b, the delay time of the second data signal may be greater than the delay time of the first data signal. Accordingly, a difference may occur in the time at which the semiconductor chip 240b receives each of the first data signal and the second data signal.

According to an embodiment of the present disclosure, the first signal interconnection pattern 280b may form a first pattern extending in the first direction, parallel to the upper surface of the base substrate 210a, and a plurality of second patterns may be formed, protruding from the first pattern in a second direction, perpendicular to the first direction and parallel to the upper surface of the base substrate 210b. The first signal interconnection pattern 280b may be formed to include the first pattern and the second patterns, thus increasing a magnitude of the capacitance generated between the first signal interconnection pattern 280b and at least one power interconnection pattern around (e.g., arranged to surround) the first signal interconnection pattern 280b. The magnitude of the capacitance generated between the first signal interconnection pattern 280b and the surrounding power interconnection pattern may be increased, thus increasing the delay time of the first data signal. With the increase in the delay time of the first data signal, a difference between the delay time of the first data signal and the delay time of the second data signal may be reduced or eliminated to reduce or prevent the deterioration of signal characteristics.

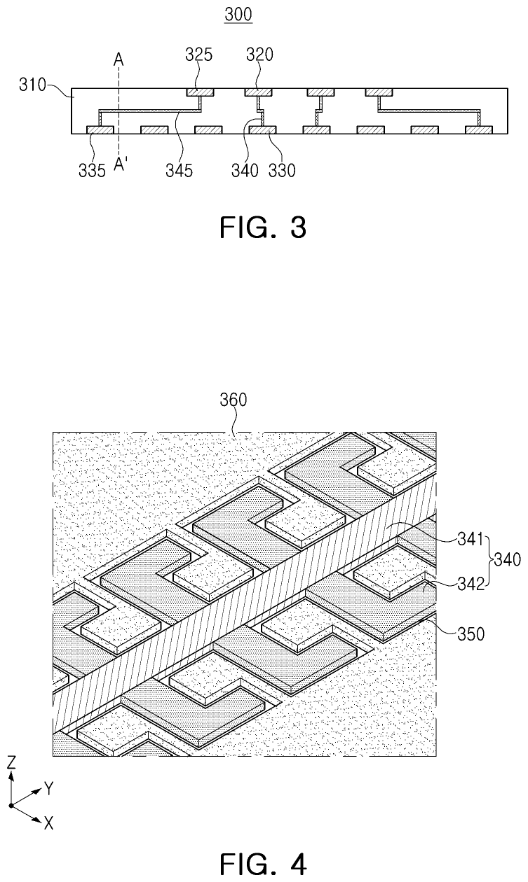

FIG. 3 is a view schematically illustrating a package substrate according to an embodiment of the present disclosure.

Referring to FIG. 3, a package substrate 300 according to an embodiment of the present disclosure may include a base substrate 310, upper pads 320 and 325, and lower pads 330 and 335. The upper pads 320 and 325 may be disposed on an upper surface of the base substrate 310, and the lower pads 330 and 335 may be disposed on a lower surface of the base substrate 310. The upper pads 320 and 325 and the lower pads 330 and 335 may be connected to interconnection patterns 340 and 345, respectively.

In an embodiment shown in FIG. 3, the upper pads 320 and 325 disposed on an upper surface of the package substrate 300 may be disposed to be connected to (e.g., electrically connected thereto) a semiconductor chip having a center pad structure. The center pad structure may be defined as a structure in which chip pads exposed to the outside of a semiconductor chip are disposed in a region relatively close to a center of the semiconductor chip.

In an embodiment, the upper pads 320 and 325 may be disposed in a region relatively close to a center of the upper surface of the base substrate 310 in one direction, parallel to the upper surface of the base substrate 310 for connection to (e.g., electrically connection thereto) chip pads disposed in the center pad structure in the semiconductor chip. Due to such structural features, at least a portion of the interconnection patterns 340 and 345 connecting (e.g., electrically connecting) the upper pads 320 and 325 and the lower pads 330 and 335 to each other may have different lengths from each other. When at least a portion of the interconnection patterns 340 and 345 have different lengths, a difference may occur in delay characteristics of signals transmitted to the signal interconnection patterns 340 and 345.

Referring to FIG. 3, a plurality of signal interconnection patterns 340 and 345 may include a first signal interconnection pattern 340 connecting (e.g., electrically connecting) the first upper pad 320 and the first lower pad 330 to each other, and a second signal interconnection pattern 345 connecting (e.g., electrically connecting) the second upper pad 325 and the lower pad 335 to each other. In an embodiment, the first signal interconnection pattern 340 may provide a transmission path for a first data signal, and the second signal interconnection pattern 345 may provide a transmission path for a second data signal. Due to a difference in length between the first signal interconnection pattern 340 and the second signal interconnection pattern 345, when the first data signal and the second data signal are simultaneously input to the first lower pad 330 and the second lower pad 335, the time at which the first data signal and the second data signal arrive at the first upper pad 320 and the second upper pad 325 may be different from each other. Accordingly, a difference between the delay time of the first data signal and the delay time of the second data signal may occur.

For example, in an embodiment the shortest distance between the first upper pad 320 and the first lower pad 330 may be less than the shortest distance between the second upper pad 325 and the second lower pad 335. Accordingly, in an embodiment in which each of the first signal interconnection pattern 340 and the second signal interconnection pattern 345 is formed with the shortest distance, a length of the first signal interconnection pattern 340 may be less than a length of the second signal interconnection pattern 345. Due to the difference in length between the first signal interconnection pattern 340 and the second signal interconnection pattern 345, the delay time of the first data signal may be less than the delay time of the second data signal.

In an embodiment of the present disclosure, the first signal interconnection pattern 340 may include a first pattern extending in the first direction, parallel to the upper surface of the base substrate 310, and a plurality of second patterns protruding from the first pattern in the second direction, perpendicular to the first direction and parallel to the upper surface of the base substrate 310. In an embodiment, at least one power interconnection pattern may be disposed around (e.g., arranged to surround) the first signal interconnection pattern 340 so that the at least one power interconnection pattern is adjacent to the first signal interconnection pattern 340 in the first direction and the second direction. By forming the first signal interconnection pattern 340 to include the first pattern and the second patterns, an area where the first signal interconnection pattern 340 and the surrounding power interconnection pattern face each other may be expanded. In an embodiment, the power interconnection pattern may provide a ground voltage path. For example, the power interconnection pattern may be a supply path for the ground voltage.

When the area in which the first signal interconnection pattern 340 and the surrounding power interconnection pattern face each other is expanded, the magnitude of the capacitance generated between the first signal interconnection pattern 340 and the surrounding power interconnection pattern may increase, thereby increasing the delay time of the first data signal. By increasing the delay time of the first data signal, the difference between the delay time of the first data signal and the delay time of the second data signal may be eliminated or reduced to prevent or reduce the deterioration of signal characteristics.

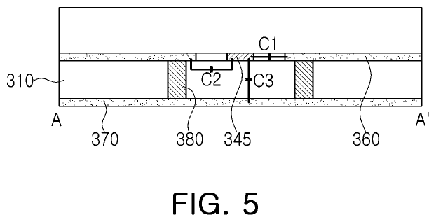

FIG. 4 is a perspective view schematically illustrating a portion of an interconnection pattern according to an embodiment of the present disclosure.

FIG. 4 may be a view illustrating in detail at least one of the signal interconnection patterns 340 and 345 included in the package substrate 300 according to an embodiment illustrated in FIG. 3. Referring to FIG. 4, the package substrate 300 according to an embodiment of the present disclosure may include at least one signal interconnection pattern 340 and at least one power interconnection pattern 360. In an embodiment, the signal interconnection pattern 340 may form a first pattern 341 extending in the first direction (e.g., the Y-axis direction) and a plurality of second patterns 342 protruding from the first pattern 341 in a second direction (e.g., the X-axis direction), perpendicular to the first direction. In an embodiment, at least one power interconnection pattern 360 may be disposed around the signal interconnection pattern 340 and the power interconnection pattern 360 may have a shape surrounding the signal interconnection pattern 340. A space 350 may be formed between the signal interconnection pattern 340 and the surrounding power interconnection pattern 360. In an embodiment, the base substrate 310 or air may be present in the space 350. For example, as illustrated in FIG. 4, the power interconnection pattern 360 may have a shape corresponding to the first pattern 341 and the second patterns 342, and may be a supply path for a ground voltage.

$$C = ε * A / d \qquad Equation 1$$

$${t}_{pd} = \sqrt{L * C} \qquad Equation 2$$

In Equation 1 above, C may refer to a capacitance generated between the signal interconnection pattern 340 and the power interconnection pattern 360 surrounding the signal interconnection pattern 340. ε may refer to a dielectric constant of a material disposed between the signal interconnection pattern 340 and the surrounding power interconnection pattern 360. A may refer to a region in which the signal interconnection pattern 340 and the surrounding power interconnection pattern 360 face each other. d may refer to a gap between the signal interconnection pattern 340 and the surrounding power interconnection pattern 360. As an area A in which the signal interconnection pattern 340 and the surrounding power interconnection pattern 360 face each other is expanded, the magnitude of the capacitance C generated between the signal interconnection pattern 340 and the surrounding power interconnection pattern 360 may be increased. Additionally, as a gap d between the signal interconnection pattern 340 and the surrounding power interconnection pattern 360 narrows, a magnitude of the capacitance C generated between the signal interconnection pattern 340 and the surrounding power interconnection pattern 360 may be increased.

In Equation 1 above, t_{pd} may refer to the delay time required for a signal to reach from the lower pads 330 and 335 of the package substrate 300 to the upper pads 320 and 325 through a transmission path provided by the signal interconnection patterns 340 and 345. L may refer to inductance formed inside the interconnection patterns 340 and 345 in the package substrate 300. With an increase in a size of the inductance L or capacitance C inside the signal interconnection patterns 340 and 345, the delay time t_{pd} may be increased.

In an embodiment of the present disclosure, the delay time t_{pd} may be adjusted by adjusting the magnitude of the capacitance C. Since there is a difference in physical lengths of each signal interconnection pattern 340 and 345, the magnitude of the capacitance C of each signal interconnection patterns 340 and 345 may vary to reduce or eliminate a difference in delay time t_{pd} between the respective signal interconnection patterns 340 and 345.

According to an embodiment of the present disclosure, the signal interconnection pattern 340 includes a first pattern 341 extending in the first direction and a plurality of plurality of patterns protruding from the first pattern 341 in the second direction, perpendicular to the first direction. Second patterns 342 may be formed. For example, in an embodiment as shown in FIG. 4, the second patterns 342 may have an L-shape protruding from the first pattern 341 in the X-direction perpendicular to the extending direction, such as the Y-direction, of the first pattern 341. However, embodiments of the present disclosure are not necessarily limited thereto and the second patterns 342 may have various different shapes protruding from the first pattern 341 in the second direction, such as the X-direction. As compared to a case in which the signal interconnection pattern 340 includes only the first pattern 341, since the signal interconnection pattern 340 includes the first pattern 341 and the second patterns 342, an area A in which the signal interconnection pattern 340 and the surrounding power interconnection pattern 360 face each other may be expanded. With the increase in the area A in which the signal interconnection pattern 340 and the surrounding power interconnection pattern 360 face each other, the magnitude of the capacitance C may be increased, and thus, the delay time t_{pd} of the signal may be increased.

In an embodiment illustrated in FIG. 3, at least one power interconnection pattern 360 may be disposed around (e.g., arranged to surround) each of the first signal interconnection pattern 340 providing the transmission path for the first data signal and the second signal interconnection pattern 345 providing the transmission path for the second data signal. In this embodiment, a gap between the first signal interconnection pattern 340 and the surrounding power interconnection pattern 360 may be less than a gap between the second signal interconnection pattern 345 and the surrounding power interconnection pattern 360.

As previously described with reference to FIG. 4, as the gap d between the first signal interconnection pattern 340 and the surrounding power interconnection pattern 360 decreases, the magnitude of the capacitance size may be increased. The gap between the first signal interconnection pattern 340 and the surrounding power interconnection pattern 360 may be formed to be relatively narrow, the delay time of the first signal interconnection pattern 340 may be set to be greater than the delay time of the second signal interconnection pattern 345.

According to an embodiment of the present disclosure, the signal interconnection pattern 340 may be formed to include the first pattern 341 and the second patterns 342, or the area A in which the signal interconnection pattern 340 and the surrounding power interconnection pattern 360 face each other may be increased, thus increasing the delay time t_{pd} of the signal interconnection pattern 340. Alternatively, the gap d between the signal interconnection pattern 340 and the surrounding power interconnection pattern 360 may be reduced to increase the delay time t_{pd} of the signal interconnection pattern 340.

In an embodiment, the area A in which the signal interconnection patterns 340 and 345 and the surrounding power interconnection patterns 360 face each other and/or the gap d between the signal interconnection patterns 340 and 345 and the surrounding power interconnection patterns 360 may be adjusted to compensate for the delay time t_{pd} of the signal, so that the delay time t_{pd} may be increased even without increasing the length of the signal interconnection patterns 340 and 345, thereby reducing an area that the signal interconnection patterns 340 and 345 occupy on the package substrate 300. Accordingly, the miniaturization of the semiconductor package may be achieved, and the difference in delay time t_{pd} may be reduced or eliminated to increase the characteristics of signals transmitted and received by the semiconductor chip.

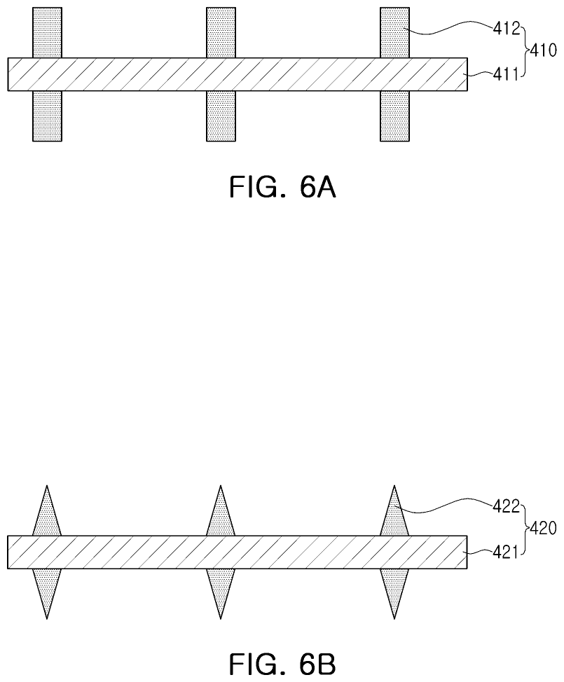

FIG. 5 is a view schematically illustrating an interconnection pattern according to an embodiment of the present disclosure.

FIG. 5 may be a cross-sectional view illustrating a cross-section in direction A-A′ of FIG. 3. The package substrate 300 according to an embodiment of the present disclosure may include a base substrate 310, a signal interconnection pattern 345, a power interconnection pattern 360, and a ground layer 370. In an embodiment, at least one power interconnection pattern 360 may surround the signal interconnection pattern 345 and may have a shape corresponding to a shape of the signal interconnection pattern 345, thus providing a supply path for a ground voltage. Additionally, the ground layer 370 may be disposed on a lower surface of the base substrate 310, may have an area greater than a region of each of the plurality of interconnection patterns 345, and may be provided with the ground voltage. In an embodiment, the power interconnection pattern 360 and the ground layer 370 may be connected (e.g., electrically connected) to each other through a via 380.

Referring to FIG. 5, a first capacitance C1 and a second capacitance C2 may be generated between the signal interconnection pattern 345 and the surrounding power interconnection pattern 360. Additionally, a third capacitance C3 may be generated between the signal interconnection pattern 345 and the ground layer 370.

In an embodiment, the power interconnection pattern 360 may be disposed on the same plane (e.g., in the thickness direction of the base substrate 310, such as the Z-direction) as the signal interconnection pattern 345, and the ground layer 370 may be further disposed below the signal interconnection pattern 345, so that a size of the total capacitance reflected in the signal interconnection pattern 345 may be increased by generating the first to third capacitances C1 to C3. The size of the total capacitance reflected in the signal interconnection pattern 345 may be increased to increase the delay time of the signal transmitted through the signal interconnection pattern 345.

In an embodiment illustrated in FIG. 5, the ground layer 370 may be disposed on the lower surface of the base substrate 310 to further form the third capacitance C3, so that the delay time of the signal may be further increased as compared to the case in which only the power interconnection pattern 360 is disposed. Since the delay time of the signal may be increased without separately increasing the length of the signal interconnection pattern 345, an area of the signal interconnection pattern 345 occupied on the package substrate may be reduced. Accordingly, the miniaturization of the semiconductor package may be achieved, and the difference in delay time may be reduced or eliminated to increase the characteristics of signals transmitted and received by a semiconductor chip.

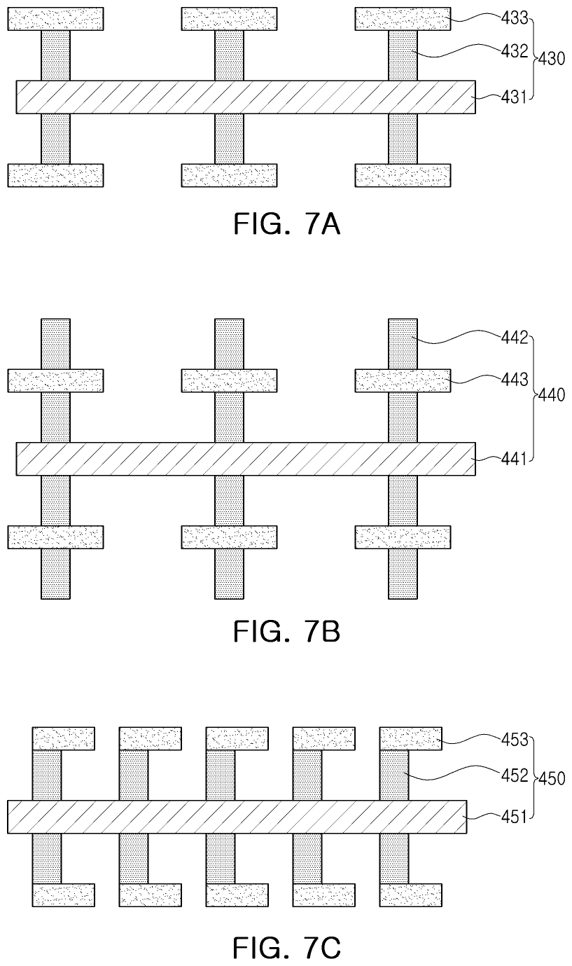

FIGS. 6A to 8C are views schematically illustrating a portion of an interconnection pattern according to an embodiment of the present disclosure.

In an embodiment of the present disclosure, to reduce the delay time difference between data signals transmitted through signal interconnection patterns, at least one signal interconnection pattern among the signal interconnection patterns may form a first pattern extending in the first direction, parallel to the upper surface of the base substrate, and a plurality of second patterns protruding from the first pattern in a second direction, perpendicular to the first direction and parallel to the upper surface of the base substrate. In this embodiment, the second patterns of the signal interconnection pattern may have various shapes, and the signal interconnection pattern may form third patterns extending from the second patterns in the first direction. Additionally, the second patterns of the signal interconnection pattern may be disposed in various positions in the first direction from the first pattern. Hereinafter, various examples of the second patterns may be described with reference to FIGS. 6A to 8C.

Referring to embodiments shown in FIGS. 6A and 6B together, signal interconnection patterns 410 and 420 may form first patterns 411 and 421 extending in a first direction (e.g., a horizontal direction) and a plurality of second patterns 412 and 422 protruding from the first patterns 411 and 421 in the second direction, perpendicular to the first direction. Each of the second patterns 412 and 422 may have a rectangular shape 412 or a triangular shape 422. However, the second patterns 412 and 422 are not necessarily limited to only rectangular and triangular shapes and may have other shapes.

As previously described, at least one power interconnection pattern providing a supply path for a ground voltage may be disposed around the signal interconnection patterns 410 and 420. At least one power interconnection pattern may surround the signal interconnection patterns 410 and 420, and may have a shape corresponding to the first patterns 411 and 421 and the second patterns 412 and 422. The first patterns 411 and 421 as well as the second patterns 412 and 422 may be included in the signal interconnection patterns 410 and 420, so that an area in which the signal interconnection patterns 410 and 420 and the surrounding power interconnection patterns face each other may be expanded. Accordingly, a magnitude of the capacitance generated between the signal interconnection patterns 410 and 420 and the surrounding power interconnection patterns may be increased. With the increase in the magnitude of the capacitance, the delay time of the signal may be increased.

According to an embodiment of the present disclosure, the plurality of signal interconnection patterns 410 and 420 may form a first signal interconnection pattern 410 transmitting a first data signal and a second signal interconnection pattern 420 transmitting a second data signal. The second patterns 412 of the first signal interconnection pattern 410 and the second patterns 422 of the second signal interconnection pattern 420 may have different shapes from each other. The second patterns 412 of the first signal interconnection pattern 410 and the second patterns 422 of the second signal interconnection pattern 420 may form different shapes, so that a magnitude of the capacitance generated between the first signal interconnection pattern 410 and the surrounding power interconnection patterns may be different from a magnitude of the capacitance generated between the second signal interconnection pattern 420 and the surrounding power interconnection patterns. Accordingly, the delay time of the first data signal and the delay time of the second data signal may be different from each other. The second patterns 412 and 422 of the signal interconnection patterns may be formed differently, thereby adjusting the delay time of the signal.

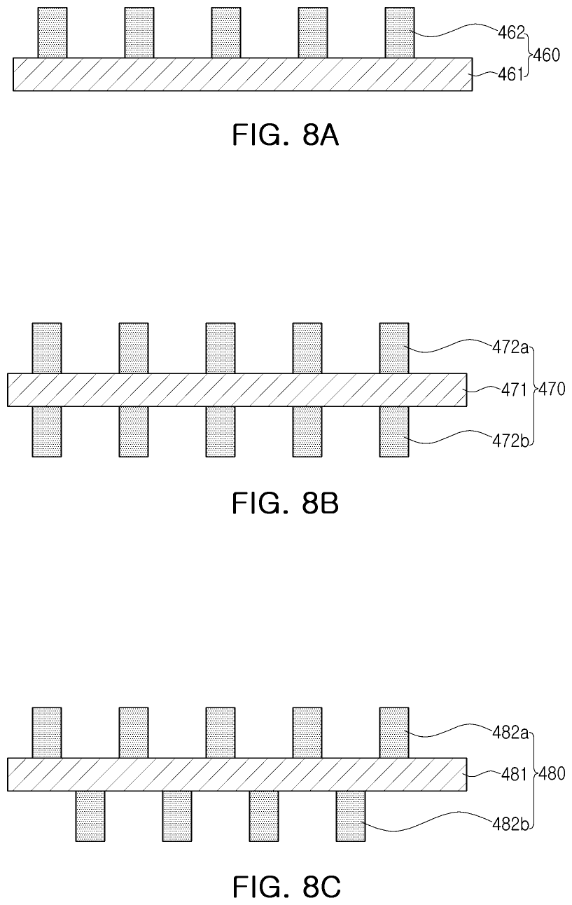

Referring to embodiments shown in FIGS. 7A to 7C together, signal interconnection patterns 430, 440 and 450 may form first patterns 431, 441 and 451 extending in the first direction, and a plurality of second patterns 432, 442 and 452 protruding from the first patterns 431, 441 and 451 in the second direction, perpendicular to the first direction. Additionally, at least one signal interconnection pattern may form third patterns 433, 443 and 453 extending from the second patterns 432, 442 and 452 in the first direction. One of the second patterns 432, 442 and 452 may be connected to one of the third patterns 433, 443 and 453 and may have at least one of a ¬ shape (e.g., an L-shape which may include a regular orientation or an inverted orientation), a T shape, and a cross shape. However, a shape in which one of the second patterns 432, 442 and 452 is connected to one of the third patterns 433, 443 and 453 is not necessarily limited to the 7 shape (e.g., an L-shape), the T shape, and the cross shape, and may have other shapes.

As described above, at least one power interconnection pattern providing the supply path for the ground voltage may be disposed around the signal interconnection patterns 430, 440 and 450. The at least one power interconnection pattern may surround the signal interconnection patterns 430, 440 and 450, and may have a shape corresponding to the first patterns 431, 441 and 451, the second patterns 432, 442 and 452, and the third patterns 433, 443 and 453. The first patterns 431, 441 and 451 as well as the second patterns 432, 442 and 452 and third patterns 433, 443 and 453 may be included in the signal interconnection patterns 430, 440 and 450. Thus, an area in which the signal interconnection patterns 430, 440 and 450 and the surrounding power interconnection patterns face each other may be expanded. Accordingly, the magnitude of the capacitance generated between the signal interconnection patterns 430, 440 and 450 and the surrounding power interconnection patterns may be increased, and the delay time of the signal may be increased.

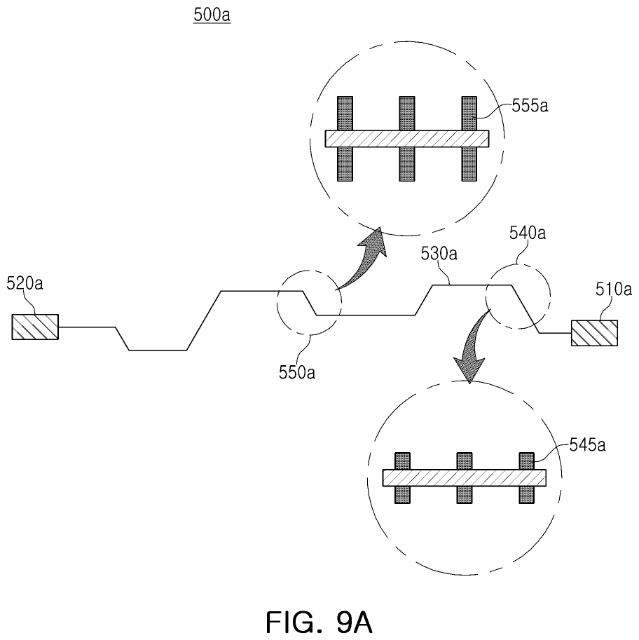

Referring to FIG. 8A, at least one signal interconnection pattern 460 may form a first pattern 461 extending in the first direction and a plurality of second patterns 462 protruding from the first pattern 461 in the second direction, perpendicular to the first direction. In an embodiment, the second patterns 462 may protrude from only one side (e.g., a first side) of the first pattern 461 in the second direction and may be arranged at regular intervals in the first direction. In an embodiment, the signal interconnection pattern 460 may form third patterns extending from the second patterns 462 in the first direction.

Referring to FIG. 8B, at least one signal interconnection pattern 470 may form a first pattern 471 extending in the first direction and a plurality of second patterns 472a and 472b protruding from the first pattern 471 in the second direction, perpendicular to the first direction. In an embodiment, the second patterns 472a and 472b may protrude in the second direction from both sides of the first pattern 471, and a portion of the second patterns 472a protruding from one side (e.g., a first side) of the first pattern 471 in the second direction may be disposed in the same position in the first direction as the remaining second patterns 472b protruding in the second direction from the other side (e.g., a second side) of the first pattern 471. In an embodiment, the signal interconnection pattern 470 may form third patterns extending from the second patterns 472a and 472b in the first direction.

Referring to FIG. 8C, at least one signal interconnection pattern 480 may form a first pattern 481 extending in the first direction and a plurality of second patterns 482a and 482b protruding from the first pattern 481 in the second direction, perpendicular to the first direction. The second patterns 482a and 482b may include some second patterns 482a protruding from one side of the first pattern 481 in the second direction, and the remaining second patterns 482b protruding from the other side of the first pattern 481 in the second direction, and a portion of the second patterns 482a and the remaining second patterns 482b may be disposed in different positions in the first direction. For example, second patterns 482a protruding from one side of the first pattern 481 in the second direction may not overlap (e.g., in the second direction) with the second patterns 482b protruding from the other side of the first pattern 481 in the second direction. In an embodiment, the signal interconnection pattern 480 may form third patterns extending from the second patterns 482a and 482b in the first direction.

Referring to embodiments shown in FIGS. 8A to 8C together, the signal interconnection patterns 460, 470, and 480 may form first patterns 461, 471 and 481, and the second patterns 462, 472a, 472b, 482a and 482b may be disposed in different positions from the first patterns 461, 471 and 481 in the first direction. The second patterns 462, 472a, 472b, 482a and 482b of the signal interconnection patterns 460, 470 and 480 may be disposed in different positions from each other, so that an area in which the signal interconnection patterns 460, 470 and 480 face the power interconnection pattern providing a ground voltage path therearound may be adjusted differently. The area in which the signal interconnection patterns 460, 470 and 480 face the surrounding power interconnection pattern may be differently adjusted, so that the magnitude of the capacitance generated between the signal interconnection patterns 460, 470 and 480 and the surrounding power interconnection patterns may be changed. When the magnitude of the capacitance is increased, the delay time of the signal may be increased.

According to an embodiment of the present disclosure, the signal interconnection patterns 460 and 470 may include a first signal interconnection pattern 460 transmitting a first data signal, and a second signal interconnection pattern 470 transmitting a second data signal. The number of second patterns 462 of the first signal interconnection pattern 460 may be different from the number of second patterns 472a and 472b of the second signal interconnection pattern 470. When the number of second patterns 462 of the first signal interconnection pattern 460 and the number of second patterns 472a and 472b of the second signal interconnection pattern 470 are different from each other, the magnitude of the capacitance generated between the first signal interconnection pattern 460 and the surrounding power interconnection pattern may be different from the magnitude of the capacitance generated between the second signal interconnection pattern 470 and the surrounding power interconnection pattern. Accordingly, the delay time of the first data signal and the delay time of the second data signal may be different from each other. Different numbers of second patterns 462, 472a and 472b included in the signal interconnection patterns 460 and 470 may be formed to adjust the delay time of the signal.

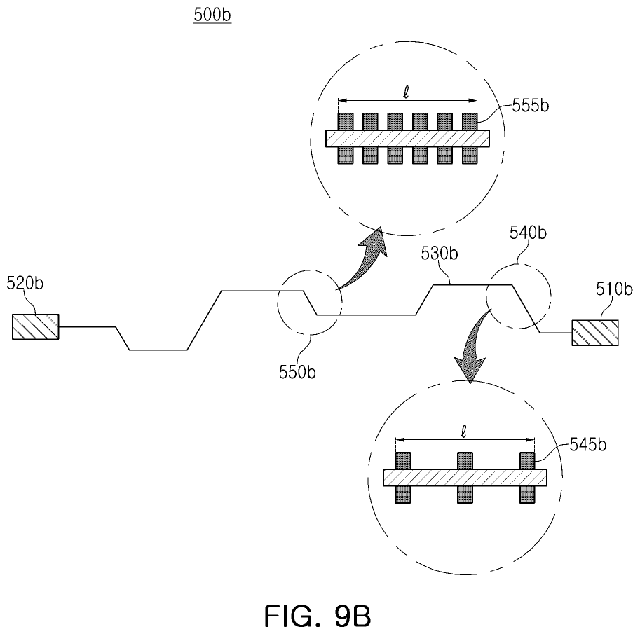

FIGS. 9A and 9B are enlarged views illustrating a portion of an interconnection pattern according to embodiments of the present disclosure.

Referring to an embodiment shown in FIG. 9A, at least one signal interconnection pattern 530a may include a first region 540a defined in (e.g., disposed in) a first distance from an upper pad 510a, and a second region 550a defined in (e.g., disposed in) a second distance greater than the first distance from the upper pad 510a. In an embodiment, a length of the second patterns 545a disposed in the first region 540a may be less than a length of the second patterns 555a disposed in the second region 550a.

According to an embodiment of the present disclosure, the signal delay time may be increased by forming the signal interconnection pattern 530a to include the first pattern and the second patterns 545a and 555a. At the same time, a length of a portion of the second patterns 545a disposed in the first region 540a may be made less than a length of the second patterns 555a disposed in the second region 550a, thus reducing or eliminating a signal loss that may occur in a portion in which the upper pad 510a or the lower pad 520a is connected to the signal interconnection pattern 530a. Accordingly, the signal interconnection pattern 530a may increase the delay time by forming the second patterns 545a and 555a, and the signal loss may be reduced or eliminated by relatively shortening the length of a portion of the second patterns 545a in the first region 540a.

Referring to an embodiment shown in FIG. 9B, at least one signal interconnection pattern 530b may include a first region 540b defined in a first distance from the upper pad 510b, and a second region 550b defined in a second distance farther than the first distance from the upper pad 510b. In an embodiment, the total number of the second patterns 545b disposed in the first region 540b having a constant length 1 may be less than the total number of second patterns 555b disposed in the second region 550b having the constant length 1.

According to an embodiment of the present disclosure, the signal interconnection pattern 530b may be formed to include the first pattern and the second patterns, thus increasing the delay time of the signal. Additionally, as illustrated in FIG. 9B, the total number of the second patterns 545b disposed in a predetermined length 1 in the first region 540b may be made less than the total number of second patterns 555b disposed inside the same length 1 in the second region 550b, reducing or eliminating a signal loss that may occur in a portion in which the upper pad or the lower pad is connected to the signal interconnection pattern 530b. Accordingly, the signal interconnection pattern 530b may increase the delay time by forming the second patterns 545b and 555b, and the signal loss may be prevented or reduced by disposing a relatively small number of second patterns 545b in the first region 540b having the predetermined length 1.

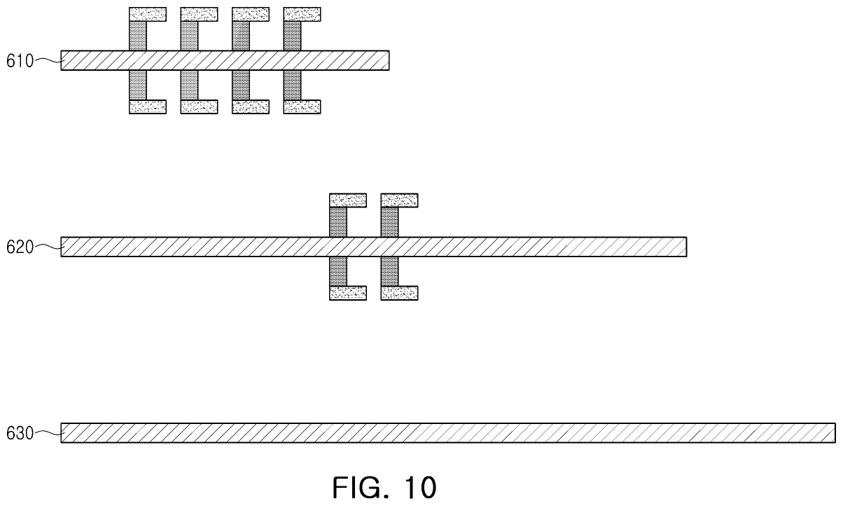

FIG. 10 is a view schematically illustrating an interconnection pattern according to an embodiment of the present disclosure.

Referring to an embodiment shown in FIG. 10, a plurality of signal interconnection patterns may include a first signal interconnection pattern 610 connecting a first upper pad and a first lower pad to each other, a second signal interconnection pattern 620 connecting a second upper pad and a second lower pad to each other, and a third signal interconnection pattern 630 connecting a third upper pad and a third lower pad to each other. In an embodiment, the first signal interconnection pattern 610 and the second signal interconnection pattern 620 may include a first pattern extending in the first direction and a plurality of second patterns protruding in the second direction perpendicular to the first direction, respectively, and the third signal interconnection pattern 630 may have only a first pattern extending in the first direction and may not include second patterns. In an embodiment, the shortest distance between the first upper pad and the first lower pad may be less than the shortest distance between the second upper pad and the second lower pad and the shortest distance between the third upper pad and the third lower pad. The shortest distance between the third upper pad and the third lower pad may be greater than the shortest distance between the first upper pad and the first lower pad and the shortest distance between the second upper pad and the second lower pad.

Since lengths of each of the signal interconnection patterns 610, 620 and 630 are different from each other, the delay time of the signal through a transmission path provided by each of the signal interconnection patterns 610, 620 and 630 may be different from each other. In a comparative embodiment in which the first signal interconnection pattern 610 and the second signal interconnection pattern 620 do not include the second patterns but only the first pattern, when the third signal interconnection pattern 630 is formed with the shortest distance, the delay time of the third signal interconnection pattern 630 may be the greatest. In an embodiment of the present disclosure, the delay time of the first signal interconnection pattern 610 and the delay time of the second signal interconnection pattern 620 may be increased in accordance with the delay time of the third signal interconnection pattern 630 to reduce or eliminate the difference in delay time. However, increasing the delay time by simply increasing the length of the first signal interconnection pattern 610 and the length of the second signal interconnection pattern 620 may cause a problem in that an area occupied by the signal interconnection patterns 610, 620 and 630 on the package substrate may be significantly increased. Accordingly, as illustrated in FIG. 10, the first signal interconnection pattern 610 and the second signal interconnection pattern 620 may be formed by including the second patterns, so that the delay time of the first signal interconnection pattern 610 and the delay time of the second signal interconnection pattern 620 may be increased, and a time difference from the delay time of the third signal interconnection pattern 630 may be reduced or eliminated. In this embodiment, the area occupied by the signal interconnection patterns 610, 620 and 630 on the package substrate may be reduced.

A package substrate according to an embodiment of the present disclosure may include a first signal interconnection pattern 610 connecting a first upper pad and a first lower pad to each other, and a second signal interconnection pattern 620 connecting a second upper pad and a second lower pad to each other. Referring to FIG. 10, the total number of second patterns included in the first signal interconnection pattern 610 may be greater than the total number of second patterns included in the second signal interconnection pattern 620. In an embodiment, at least one power interconnection pattern may be formed to surround the first signal interconnection pattern 610 and the second signal interconnection pattern 620 and provide a ground voltage supply path.

Since the number of second patterns included in the first signal interconnection pattern 610 is greater than the number of second patterns included in the second signal interconnection pattern 620, an area in which the first signal interconnection pattern 610 and the surrounding power interconnection pattern face each other may be greater than an area in which the second signal interconnection pattern 620 and the surrounding power interconnection pattern face each other. Accordingly, a magnitude of the capacitance generated between the first signal interconnection pattern 610 and the surrounding power interconnection pattern may be greater than a magnitude of the capacitance generated between the second signal interconnection pattern 620 and the surrounding power interconnection pattern. When each signal is transmitted simultaneously through a transmission path provided by the first signal interconnection pattern 610 and the second signal interconnection pattern 620, the delay time of the first signal interconnection pattern 610 with a large number of second patterns may be greater than the delay time of the second signal interconnection pattern 620 with a small number of second patterns.

In an embodiment described with reference to FIG. 10, the signal interconnection patterns 610 and 620 may include a first signal interconnection pattern 610 connecting (e.g., electrically connecting) a first upper pad and a first lower pad to each other and a second signal interconnection pattern 620 connecting (e.g., electrically connecting) a second upper pad and a second lower pad to each other. In an embodiment, the shortest distance between the first upper pad and the first lower pad may be less than the shortest distance between the second upper pad and the second lower pad. In an embodiment in which each of the first signal interconnection pattern 610 and the second signal interconnection pattern 620 is formed with the shortest distance, a length of the first signal interconnection pattern 610 may be less than a length of the second signal interconnection pattern 620, and the delay time through a transmission path provided by the first signal interconnection pattern 610 may be less than the delay time through a transmission path provided by the second signal interconnection pattern 620. The number of second patterns formed in the first signal interconnection pattern 610 may be made greater than the number of second patterns formed in the second signal interconnection pattern 620, so that a magnitude of the capacitance generated between the first signal interconnection pattern 610 and the surrounding power interconnection pattern may be greater than a magnitude of the capacitance generated between the second signal interconnection pattern 620 and the surrounding power interconnection pattern, and the delay time of the first signal interconnection pattern 610 may be increased. Accordingly, the difference between the delay time of the first signal interconnection pattern 610 and the delay time of the second signal interconnection pattern 620 may be reduced or eliminated.

In an embodiment described with reference to FIG. 10, the signal interconnection patterns 610 and 630 may include a first signal interconnection pattern 610 connecting (e.g., electrically connecting) a first upper pad and a first lower pad to each other and a third signal interconnection pattern 630 connecting (e.g., electrically connecting) a third upper pad and a third lower pad to each other. In an embodiment, the shortest distance between the first upper pad and the first lower pad may be less than the shortest distance between the third upper pad and the third lower pad. In a comparative embodiment in which each of the first signal interconnection pattern 610 and the third signal interconnection pattern 630 are formed with the shortest distance, a length of the first signal interconnection pattern 610 may be less than a length of the third signal interconnection pattern 630, and the delay time through a transmission path provided by the first signal interconnection pattern 610 may be less than the delay time through a transmission path provided by the third signal interconnection pattern 630.

In an embodiment of the present disclosure, the first signal interconnection pattern 610 may include a first pattern extending in the first direction and a plurality of second patterns protruding in the second direction, perpendicular to the first direction, and the third signal interconnection pattern 630 may include only the first pattern extending in the first direction. At least one power interconnection pattern may be formed to surround the first signal interconnection pattern 610 and the third signal interconnection pattern 630 and provide a ground voltage supply path. The first signal interconnection pattern 610 may include the first pattern and the second patterns, thereby increasing the magnitude of the capacitance generated between the first signal interconnection pattern 610 and the surrounding power interconnection pattern. When the magnitude of the capacitance generated between the first signal interconnection pattern 610 and the surrounding power interconnection pattern increases, the delay time through the transmission path provided by the first signal interconnection pattern 610 may be increased. Accordingly, the delay time of the first signal interconnection pattern 610 may be increased to reduce or eliminate a difference between the delay time of the first signal interconnection pattern 610 and the delay time of the third signal interconnection pattern 630.

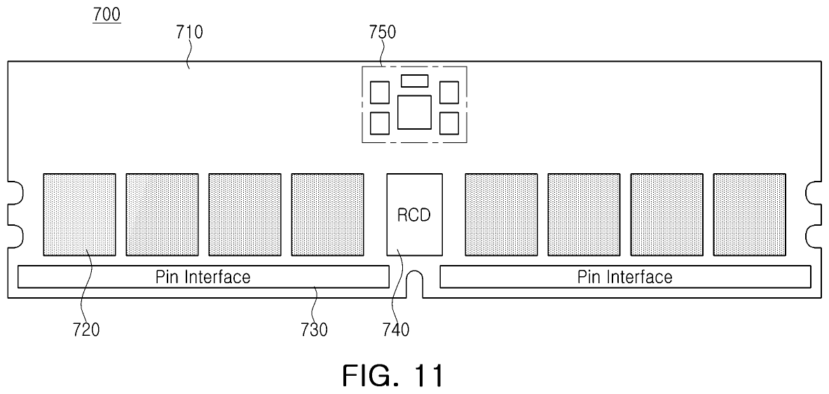

FIG. 11 is a view schematically illustrating a semiconductor package according to an embodiment of the present disclosure.

Referring to FIG. 11, a memory module 700 according to an embodiment of the present disclosure may include a package substrate 710 and a plurality of semiconductor packages 720. Additionally, the memory module 700 may include a pin interface 730, a registered clock driver (RCD) 740, an SPD HUB, and a power module IC (PMIC) 750.

The pin interface 730 may provide connection (e.g., electrical connection) to other external semiconductor devices or substrates. The RCD 740 is a system semiconductor chip configured to buffer clock signals, which prevents signal distortion and increases integrity when transmitting and receiving data between a CPU and a memory. The RCD 740 may assist to process the semiconductor packages 720 in a rapid and stable manner. The PMIC 750 may be a power semiconductor configured to convert, distribute, and control power input to the semiconductor packages 720 appropriately for the semiconductor packages 720.

Each of the semiconductor packages 720 according to an embodiment of the present disclosure may include a package substrate and a semiconductor chip mounted on the package substrate. The package substrate may include a plurality of interconnection patterns respectively connecting (e.g., electrically connecting) the plurality of upper pads and the plurality of lower pads to each other. The plurality of interconnection patterns may include signal interconnection patterns and power interconnection patterns. At least one signal interconnection pattern may include a first pattern extending in the first direction and second patterns protruding from the first pattern in the second direction, perpendicular to the first direction. Additionally, the power interconnection pattern may be disposed around the signal interconnection pattern including the first pattern and the second patterns. The power interconnection pattern may provide a supply path for a ground voltage.

The number of the second patterns and third patterns shown in FIGS. 4, 6A-10 and the size of the first and second patterns are not necessarily limited to those shown in the drawings and may vary. Additionally, while the first and second directions have been shown as being perpendicular to each other, the first and second directions may cross each other at various different angles in some embodiments.

What is claimed is:

1. A package substrate, comprising:
a base substrate;
a plurality of upper pads disposed on an upper surface of the base substrate;
a plurality of lower pads disposed on a lower surface of the base substrate; and
a plurality of interconnection patterns respectively connecting the plurality of upper pads and the plurality of lower pads to each other, the plurality of interconnection patterns including signal interconnection patterns and power interconnection patterns,
wherein at least one signal interconnection pattern among the signal interconnection patterns includes a first pattern extending in a first direction and a plurality of second patterns protruding from the first pattern in a second direction perpendicular to the first direction, and
at least one power interconnection pattern among the power interconnection patterns surrounds the at least one signal interconnection pattern, the at least one power interconnection pattern has a shape corresponding to the first pattern and the plurality of second patterns, the at least one power interconnection pattern is a supply path for a ground voltage.

2. The package substrate of claim 1, wherein:
the at least one signal interconnection pattern includes a first region disposed a first distance from the plurality of upper pads, and a second region disposed a second distance farther than the first distance from the upper pad; and
among the plurality of second patterns, a length of the plurality of second patterns that are disposed in the first region is less than a length of the plurality of second patterns that are disposed in the second region.

3. The package substrate of claim 1, wherein:
the signal interconnection patterns include a first signal interconnection pattern connecting a first upper pad of the plurality of upper pads and a first lower pad of the plurality of lower pads to each other, and a second signal interconnection pattern connecting a second upper pad of the plurality of upper pads and a second lower pad of the plurality of lower pads to each other; and
a number of second patterns included in the first signal interconnection pattern is greater than a number of the plurality of second patterns included in the second signal interconnection pattern.

4. The package substrate of claim 3, wherein a shortest distance between the first upper pad and the first lower pad is less than a shortest distance between the second upper pad and the second lower pad.

5. The package substrate of claim 1, wherein the plurality of second patterns protrude from one side of the first pattern in the second direction and are arranged at regular intervals in the first direction.

6. The package substrate of claim 1, wherein:
the plurality of second patterns protrude from both sides of the first pattern in the second direction; and
the plurality of second patterns that protrude from a first side of the first pattern in the second direction is disposed in a same position in the first direction as the plurality of second patterns that protrude in the second direction from an opposite second side of the first pattern.

7. The package substrate of claim 1, wherein:
the plurality of second patterns include a portion of the plurality of second patterns that protrude from a first side of the first pattern in the second direction, and a remainder of the plurality of second patterns protrude from an opposite second side of the first pattern in the second direction; and
in the first direction, the portion of the plurality of second patterns and the remainder of the plurality of second patterns are disposed in different positions from each other.

8. The package substrate of claim 1, wherein each of the plurality of second patterns has at least one of a rectangular shape and a triangular shape.

9. The package substrate of claim 1, wherein the at least one signal interconnection pattern includes third patterns extending from the plurality of second patterns in the first direction.

10. The package substrate of claim 9, wherein one of the plurality of second patterns is connected to one of the third patterns and the interconnection pattern is arranged in at least one of an L-shape, a T-shape, and a cross shape.

11. The package substrate of claim 1, wherein:
the signal interconnection patterns include a first signal interconnection pattern connecting the first upper pad and the first lower pad to each other, and a second signal interconnection pattern connecting the second upper pad and the second lower pad to each other;
a gap between the first signal interconnection pattern and the at least one power interconnection pattern is less than the gap between the second signal interconnection pattern and the at least one power interconnection pattern.

12. A package substrate, comprising:
a semiconductor chip mounted on the package substrate,
wherein the package substrate includes:
a base substrate;
a plurality of upper pads disposed on an upper surface of the base substrate;
a plurality of lower pads disposed on a lower surface of the base substrate; and
a plurality of interconnection patterns respectively connecting the plurality of upper pads and the plurality of lower pads to each other, the plurality of interconnection patterns including signal interconnection patterns and power interconnection patterns,
wherein at least one of the signal interconnection patterns includes a first pattern extending in a first direction and a plurality of second patterns protruding from the first pattern in a second direction perpendicular to the first direction, and
at least one power interconnection pattern among the power interconnection patterns surrounds the at least one signal interconnection pattern, the at least one power interconnection pattern has a shape corresponding to the first pattern and the second pattern, the at least one power interconnection pattern is a supply path for a ground voltage.

13. The package substrate of claim 12, wherein the semiconductor chip is disposed in a center pad structure and includes a plurality of chip pads connected to the plurality of upper pads.

14. The package substrate of claim 12, wherein the semiconductor chip is disposed in an edge pad structure and includes a plurality of chip pads connected to each of the plurality of upper pads through a wire.

15. The package substrate of claim 12, wherein:
the signal interconnection patterns include a first signal interconnection pattern transmitting a first data signal, and a second signal interconnection pattern transmitting a second data signal; and
the first signal interconnection pattern solely includes the first pattern, and the second signal interconnection pattern includes both the first pattern and a second pattern of the plurality of second patterns.

16. The package substrate of claim 12, wherein:
the signal interconnection patterns include a first signal interconnection pattern transmitting a first data signal, and a second signal interconnection pattern transmitting a second data signal; and
second patterns of the plurality of second patterns of the first signal interconnection pattern and second patterns of the plurality of second patterns of the second signal interconnection pattern have different shapes from each other.

17. The package substrate of claim 12, wherein:
the signal interconnection patterns include a first signal interconnection pattern transmitting a first data signal, and a second signal interconnection pattern transmitting a second data signal; and
a number of the plurality of second patterns of the first signal interconnection pattern is different from a number of the plurality of second patterns of the second signal interconnection pattern.

18. The package substrate of claim 12, wherein the at least one signal interconnection pattern includes third patterns extending from the plurality of second patterns in the first direction.

19. The package substrate of claim 18, wherein one of the plurality second patterns is connected to one of the third patterns and the interconnection pattern is arranged in at least one of an L-shape, a T-shape, and a cross shape.

20. A package substrate, comprising:
a base substrate;
a plurality of upper pads disposed on an upper surface of the base substrate;
a plurality of lower pads disposed on a lower surface of the base substrate; and
a plurality of interconnection patterns respectively connecting the plurality of upper pads and the plurality of lower pads to each other, the plurality of interconnection patterns including signal interconnection patterns and power interconnection patterns,
wherein at least one signal interconnection pattern among the signal interconnection patterns includes a first pattern extending in a first direction and a plurality of second patterns protruding from the first pattern in a second direction perpendicular to the first direction, and
the package substrate includes a ground layer disposed on the lower surface of the base substrate, the ground layer having an area larger than an area of each of the plurality of interconnection patterns, the ground layer receiving a ground voltage.
